(19) United States
(12) Patent Application Publication
(10) Pub. No.: US 2026/0251908 A1
(43) Pub. Date: Aug. 27, 2026

(54) POLARIZING BEAM SPLITTER AND PREPARATION METHOD AND USE THEREOF

(71) Applicant: SHANGHAI INSTITUTE OF TECHNICAL PHYSICS, CAS, Shanghai (CN)

(72) Inventors: Weibo Duan, Shanghai (CN); Daqi Li, Shanghai (CN); Baojian Liu, Shanghai (CN); Deming Yu, Shanghai (CN); Qiujing Ma, Shanghai (CN); Qinglin Yang, Shanghai (CN); Tianyan Yu, Shanghai (CN); Qingyuan Cai, Shanghai (CN); Dejian Zhang, Shanghai (CN); Tongyu Zhao, Shanghai (CN)

(21) Appl. No.: 19/649,103

(22) Filed: Apr. 15, 2026

Related U.S. Application Data
(63) Continuation-in-part of application No. PCT/CN2024/132593, filed on Nov. 18, 2024.

(30) Foreign Application Priority Data
Oct. 29, 2024 (CN) 202411514738.X

(51) Int. Cl. G02B 27/28; G02B 1/115; H10P 34/42

(52) U.S. Cl. CPC G02B 27/283; G02B 1/115; H10P 34/42

(57) ABSTRACT

A polarizing beam splitter and a preparation method and use thereof are provided. The polarizing beam splitter includes a diamond substrate, a broadband anti-reflection coating and a first metallized layer located on one side surface of the diamond substrate, a polarizing beam splitting coating located on another side surface of the diamond substrate, and a second metallized layer located on a side of the diamond substrate, where the first metallized layer is located on an edge of the one side surface of the diamond substrate. Diamond is adopted as the substrate material of the polarizing beam splitter. The diamond substrate can quickly conduct heat generated by laser irradiation on the layer and the substrate, thereby mitigating damage to the polarizing beam splitter caused by local temperature rise. The metallization treatment on the edge of the polarizing beam splitter providing a high-reliability and low-leakage vacuum sealing solution.

### CROSS-REFERENCE TO RELATED APPLICATION

The present disclosure is a Continuation-In-Part Application of PCT Application No. PCT/CN2024/132593 filed on Nov. 18, 2024, which claims priority to Chinese Patent Application No. 202411514738.X, filed with the China National Intellectual Property Administration (CNIPA) on Oct. 29, 2024, and entitled “POLARIZING BEAM SPLITTER AND PREPARATION METHOD AND USE THEREOF”, which is incorporated herein by reference in its entirety.

### TECHNICAL FIELD

The present disclosure relates to the technical field of polarizing beam splitters, and in particular to a polarizing beam splitter and a preparation method and use thereof.

### BACKGROUND

Laser annealing is a process in which a laser beam irradiates the semiconductor surface, generating extremely high temperatures locally in the irradiated area to repair crystal damage and eliminate dislocations. It is an indispensable step in the manufacturing of ultra-large-scale integrated circuits.

A manufacturing process of integrated circuits imposes extremely stringent requirements on the uniformity of laser annealing. However, the “pattern effect” during laser annealing, that is, the temperature non-uniformity inside the chip caused by differences in light absorption due to device patterns, severely affects the performance and yield of devices. Research shows that infrared polarized laser with a longer wavelength incident at the Brewster angle can significantly reduce the pattern effect in laser annealing. Hence, related infrared laser annealing equipment has become a focus of attention in the semiconductor industry globally.

The polarizing beam splitter used to obtain high-performance linearly polarized light is an essential core optical component in infrared laser annealing systems. Compared with polarizing beam splitters operating in the visible and near-infrared bands, those designed for the infrared band, especially the long-wave infrared band, exhibit more pronounced thermal effects under infrared laser exposure. They have a lower laser-induced damage threshold, and face greater challenges in achieving a high extinction ratio and a high laser-induced damage threshold.

### SUMMARY

An objective of the present disclosure is to provide a polarizing beam splitter and a preparation method thereof. The polarizing beam splitter has high thermal conductivity to prevent laser damage caused by temperature rise and ensure desired optical performance.

To achieve the above objective, the present disclosure provides the following technical solutions:

The present disclosure provides a polarizing beam splitter, including: a diamond substrate 1, a broadband anti-reflection coating 3 and a first metallized layer 4-1 located on one side surface of the diamond substrate 1, a polarizing beam splitting coating 2 located on another side surface of the diamond substrate 1, and a second metallized layer 4-2 located on a side of the diamond substrate 1, where
the first metallized layer 4-1 is located on an edge of the one side surface of the diamond substrate 1, and the broadband anti-reflection coating 3 is located on a remaining area of the one side surface of the diamond substrate 1.

Preferably, the diamond substrate 1 is double-side polished, has an optical surface shape with a root mean square (RMS) value of less than 1/50 λ, and has a surface roughness of less than 0.5 nm.

Preferably, the side of the diamond substrate 1 has a surface roughness of less than 1.6 μm.

Preferably, an adhesion layer 5 is provided between the diamond substrate 1 and the first metallized layer 4-1 and between the diamond substrate 1 and the second metallized layer 4-2.

Preferably, the adhesion layer is a nickel (Ni)-chromium (Cr) alloy layer; and
a molar ratio of Ni to Cr in the Ni—Cr alloy layer is 80:20.

Preferably, the first metallized layer 4-1 and the second metallized layer 4-2 are each independently made of one or more selected from a group consisting of gold (Au), copper (Cu), Cr, and Ni.

Preferably, the first metallized layer 4-1 and the second metallized layer 4-2 each independently have a thickness ranging from 1.2 to 2.0 μm.

Preferably, the polarizing beam splitting coating 2 includes a first high-refractive-index material layer H1 and a first low-refractive-index material layer L1 that are sequentially stacked and cyclically arranged, and an innermost layer and an outermost layer of the polarizing beam splitting coating 2 are the first high-refractive-index material layer; and
a refractive index of the first high-refractive-index material layer is greater than a refractive index of the first low-refractive-index material layer.

Preferably, the first high-refractive-index material layer is made of zinc selenide (ZnSe); and
the first low-refractive-index material layer is made of barium fluoride (BaF₂) doped with ytterbium trifluoride (YbF₃).

Preferably, a doping amount of YbF₃ in BaF₂ doped with YbF₃ is 0.5-5 wt %.

Preferably, the polarizing beam splitting coating 2 has a thickness ranging from 10 to 50 μm and includes a total of 31 layers.

Preferably, the broadband anti-reflection coating 3 includes a second high-refractive-index material layer H2 and a second low-refractive-index material layer L2 that are sequentially stacked and cyclically arranged, and an innermost layer and an outermost layer of the broadband anti-reflection coating 3 are the second high-refractive-index material layer; and
a refractive index of the second high-refractive-index material layer is greater than a refractive index of the second low-refractive-index material layer.

Preferably, the second high-refractive-index material layer is made of ZnSe; and
the second low-refractive-index material layer is made of BaF₂ doped with YbF₃.

Preferably, a doping amount of YbF₃ in BaF₂ doped with YbF₃ is 0.5-5 wt %.

Preferably, the broadband anti-reflection coating 3 has a thickness ranging from 10 to 50 μm and includes a total of 39 layers.

The present disclosure further provides a preparation method of the polarizing beam splitter according to the above technical solution, including following steps:
preparing the second metallized layer 4-2 and the first metallized layer 4-1 on the side of the diamond substrate 1 and on the edge of the one side surface of the diamond substrate; then preparing the broadband anti-reflection coating 3 on a remaining area of the one side surface of the diamond substrate 1, and preparing the polarizing beam splitting coating 2 on the another side surface of the diamond substrate 1, thereby obtaining the polarizing beam splitter.

Preferably, when there is an adhesion layer 5 provided between the diamond substrate 1 and the first metallized layer 4-1 and between the diamond substrate 1 and the second metallized layer 4-2, the preparation method further includes: preparing the adhesion layer by physical vapor deposition (PVD).

The present disclosure further provides a use of the polarizing beam splitter according to the above technical solution, or a polarizing beam splitter prepared by the preparation method according to the above technical solution, in a field of an infrared laser annealing device for a semiconductor chip industry and a laser produced plasma (LPP)-driven laser light source for an extreme ultraviolet (EUV) lithography system.

The present disclosure further provides an infrared laser annealing device, including the polarizing beam splitter according to the above technical solution, or a polarizing beam splitter prepared by the preparation method according to the above technical solution.

The present disclosure further provides an LPP-driven laser light source, including the polarizing beam splitter according to the above technical solution, or a polarizing beam splitter prepared by the preparation method according to the above technical solution.

The present disclosure provides a polarizing beam splitter, including: a diamond substrate 1, a broadband anti-reflection coating 3 and a first metallized layer 4-1 located on one side surface of the diamond substrate 1, a polarizing beam splitting coating 2 located on another side surface of the diamond substrate 1, and a second metallized layer 4-2 located on a side of the diamond substrate 1, where the first metallized layer 4-1 is located on an edge of the one side surface of the diamond substrate 1.

Compared with the prior art, the technical solutions of the present disclosure have the following beneficial effects:
1) The present disclosure uses diamond as the substrate material of the polarizing beam splitter. By virtue of its high thermal conductivity, the diamond substrate can quickly conduct heat generated by laser irradiation on the layer and the substrate, thereby mitigating damage to the polarizing beam splitter caused by local temperature rise.
2) Metallization treatment on the edge of the polarizing beam splitter is performed in the present disclosure, which enables integral welding of the splitter body to a metal package or a water-cooled structure in subsequent uses. This design improves thermal conduction efficiency, and provides a high-reliability and low-leakage-rate vacuum sealing solution.

Furthermore, the optical and mechanical properties of the rare earth fluoride are improved in the present disclosure by adjusting the materials of the polarizing beam splitting coating and the broadband anti-reflection coating (through doping the rare earth fluoride). The materials are used to replace the traditional radioactive thorium fluoride (ThF₄) as the low-refractive-index material in the present disclosure, thereby ensuring environmental friendliness. By adjusting the total thickness of the broadband anti-reflection coating, the change in the splitter surface figure caused by the stress of the polarizing beam splitting coating is further offset in the present disclosure, thereby maintaining the high surface figure accuracy of the polarizing beam splitter.

### BRIEF DESCRIPTION OF THE DRAWINGS

FIG. 1 is a schematic structural diagram of a polarizing beam splitter according to the present disclosure, where 1 denotes a diamond substrate, 2 denotes a polarizing beam splitting coating, 3 denotes a broadband anti-reflection coating, 4-1 denotes a first metallized layer, 4-2 denotes a second metallized layer, and 5 denotes an adhesion layer;

FIG. 2 is a flowchart of a preparation process for the metallized layer according to the present disclosure;

FIG. 3 is a designed spectrum of the polarizing beam splitting coating according to Embodiment 1; and

FIG. 4 is a designed spectrum of the broadband anti-reflection coating according to Embodiment 1.

### DETAILED DESCRIPTION

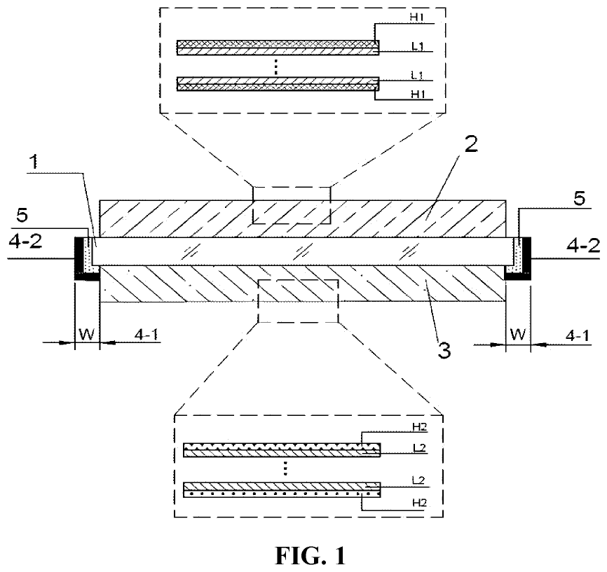

As shown in FIG. 1, the present disclosure provides a polarizing beam splitter, including a diamond substrate 1, a broadband anti-reflection coating 3 and a first metallized layer 4-1 located on one side surface of the diamond substrate 1, a polarizing beam splitting coating 2 located on another side surface of the diamond substrate 1, and a second metallized layer 4-2 located on a side of the diamond substrate 1.

The first metallized layer 4-1 is located on an edge of the one side surface of the diamond substrate 1.

In the present disclosure, the diamond substrate 1 is preferably double-side polished. A polished surface of the diamond substrate 1 has an optical surface shape with a root mean square (RMS) value of preferably less than 1/50 λ and a surface roughness of preferably less than 0.5 nm. The surface roughness of the side of the diamond substrate 1 is preferably less than 1.6 μm. There is no special restriction on the source of the diamond substrate 1 in the present disclosure, and any source well-known to those skilled in the art may be employed. In an embodiment of the present disclosure, the diamond substrate 1 may be prepared by chemical vapor deposition (CVD).

In the present disclosure, the diamond substrate 1 has a diameter of 50 mm and a thickness of 2 mm.

In the present disclosure, materials of the first metallized layer 4-1 and the second metallized layer 4-2 are each independently preferably one or more selected from a group consisting of gold (Au), copper (Cu), chromium (Cr), and nickel (Ni). When the materials of the first metallized layer 4-1 and the second metallized layer 4-2 are each independently two or more of the above specific selections, there is no special restriction on the ratio of the above specific substances in the present disclosure, and they can be mixed in any ratio. In an embodiment of the present disclosure, the first metallized layer 4-1 and the second metallized layer 4-2 are made of the same material, which may be Au.

In the present disclosure, the first metallized layer 4-1 and the second metallized layer 4-2 each independently have a thickness preferably ranging from 1.2 to 2.0 μm. In an embodiment of the present disclosure, the first metallized layer 4-1 and the second metallized layer 4-2 each may have a thickness of 1.5 μm.

In the present disclosure, a width W of the first metallized layer 4-1 may be 2 mm.

In the present disclosure, the first metallized layer 4-1 and the second metallized layer 4-2 can realize integral welding of the polarizing beam splitter to a metal package or water-cooled structure in subsequent uses. This design improves thermal conduction efficiency, and provides a high-reliability and low-leakage-rate vacuum sealing solution.

In the present disclosure, an adhesion layer 5 is preferably disposed between the diamond substrate 1 and the first metallized layer 4-1 and between the diamond substrate 1 and the second metallized layer 4-2. The adhesion layer is preferably a Ni—Cr alloy layer. A molar ratio of Ni to Cr in the Ni—Cr alloy layer is 80:20, and a thickness of the Ni—Cr alloy layer may be 50 nm.

In the present disclosure, a central wavelength of the polarizing beam splitting coating 2 is preferably 11.0 μm. The polarizing beam splitting coating 2 uses (HL)\hat{ }15 H as an initial film stack, with optimized target values of Rs≥99.5% and Rp≤0.1%. In the present disclosure, the polarizing beam splitting coating 2 preferably includes a first high-refractive-index material layer H1 and a first low-refractive-index material layer L1 that are sequentially stacked and cyclically arranged, and an innermost layer and an outermost layer of the polarizing beam splitting coating 2 are preferably the first high-refractive-index material layer H1. The first high-refractive-index material layer H1 is preferably made of zinc selenide (ZnSe). The first low-refractive-index material layer L1 is preferably made of barium fluoride (BaF₂) doped with ytterbium trifluoride (YbF₃). In the present disclosure, a doping amount of YbF₃ in BaF₂ doped with YbF₃ is preferably 0.5-5 wt %. There is no special restriction on the thickness of each layer in the polarizing beam splitting coating 2 in the present disclosure, and any thickness well-known to those skilled in the art can be used as long as it meets the requirement of total thickness and the thickness of each layer ranges from 10 nm to 10 μm. In an embodiment of the present disclosure, the doping amount of YbF₃ in BaF₂ doped with YbF₃ may be 1.5 wt %. The thickness of the polarizing beam splitting coating 2 may be 36 μm, and there may be 31 layers in total. In an embodiment of the present disclosure, the central wavelength of the polarizing beam splitting coating 2 is 11.0 μm. The polarizing beam splitting coating 2 uses (HL)\hat{ }15 H as the initial film stack, with the optimized target values of Rs≥99.5% and Rp≤0.1%.

In the present disclosure, a central wavelength of the broadband anti-reflection coating 3 is preferably 11.0 μm. The broadband anti-reflection coating 3 uses (HL))\hat{ }19 H as an initial film stack, with an optimized target value of T≥99.5%. In the present disclosure, a thickness of a single layer of the broadband anti-reflection coating 3 is preferably not greater than 2 μm. The broadband anti-reflection coating 3 preferably includes a second high-refractive-index material layer H2 and a second low-refractive-index material layer L2 that are sequentially stacked and cyclically arranged, and an innermost layer and an outermost layer of the broadband anti-reflection coating 3 are preferably the second high-refractive-index material layer H2. The second high-refractive-index material layer H2 is made of ZnSe, and the second low-refractive-index material layer L2 is preferably made of BaF₂ doped with YbF₃. A doping amount of YbF₃ in BaF₂ doped with YbF₃ is preferably 0.5-5 wt %. There is no special restriction on the thickness of each layer in the broadband anti-reflection coating 3 in the present disclosure, and any thickness well-known to those skilled in the art can be used as long as it meets the requirement of total thickness. In an embodiment of the present disclosure, the doping amount of YbF₃ in BaF₂ doped with YbF₃ may be 1.5 wt %. The thickness of the broadband anti-reflection coating 3 may be 30.5 μm, and there may be 39 layers in total. In an embodiment of the present disclosure, the central wavelength of the broadband anti-reflection coating 3 may be 11.0 μm. The broadband anti-reflection coating 3 uses (HL))\hat{ }19 H as the initial film stack, with an optimized target value of T≥99.5%. The thickness of a single layer of the broadband anti-reflection coating 3 is not greater than 2 μm.

The present disclosure further provides a preparation method of the polarizing beam splitter according to the above technical solution, which includes the following steps.

The second metallized layer 4-2 and the first metallized layer 4-1 are prepared on the side of the diamond substrate 1 and on the edge of one side surface of the diamond substrate. Then the broadband anti-reflection coating 3 is prepared on a remaining area of the one side surface of the diamond substrate 1, and the polarizing beam splitting coating 2 is prepared on another side surface of the diamond substrate 1. Thus, the polarizing beam splitter is obtained.

In the present disclosure, the second metallized layer 4-2 and the first metallized layer 4-1 are preferably deposited on the side of the diamond substrate 1 and on the edge of the one side surface of the diamond substrate by a mechanical mask or a semiconductor lift-off process. In the present disclosure, the deposition method is preferably resistive evaporation, electron beam evaporation (EBE), or sputtering. There are no special restrictions on the processes of mechanical mask, semiconductor lift-off process, resistive evaporation, EBE, or sputtering, and any process well-known to those skilled in the art may be employed in the present disclosure. In an embodiment of the present disclosure, the second metallized layer 4-2 and the first metallized layer 4-1 may be prepared by depositing the second metallized layer 4-2 and the first metallized layer 4-1 on the side of the diamond substrate 1 and on the edge of one side surface of the diamond substrate by the lift-off process. Specifically, a photoresist is uniformly applied to the one side surface of the diamond substrate. Then exposure and development are performed. After exposure and development, the diamond substrate is mounted (i.e., loaded into a sample holder). A door of a vacuum chamber is closed, and vacuum pumping is performed until a base pressure reaches 8.0×10⁻⁴ Pa. A workpiece tray is activated to rotate at a speed of 20 rpm. An ion source is turned on to perform pre-deposition bombardment cleaning on the diamond substrate for 5 min. Then the ion source is turned off, and the metallized layer is deposited on an area of the diamond substrate after the exposure and development and on two sides of the diamond substrate by resistive evaporation. First, a Ni—Cr alloy layer is deposited as the adhesion layer to improve the adhesion between a gold (Au) layer and the diamond substrate, and then the Au layer is deposited. A spiral tungsten filament is used as a resistive evaporation source for depositing the Ni—Cr alloy layer, with a deposition rate of 6.0 nm/s and a deposition thickness of 50 nm. A molybdenum boat is used as a resistive evaporation source for depositing the Au layer, with a deposition rate of 5.0 nm/s and a deposition thickness of 1.5 μm. After 30 min of preparation, a prepared sample is taken out of the vacuum chamber, and the photoresist is stripped to obtain the second metallized layer 4-2 and the first metallized layer 4-1 with a thickness of 1.5 μm.

In the present disclosure, the polarizing beam splitting coating 2 is prepared on another side surface of the diamond substrate 1. Preferably, the high-refractive-index material layer is prepared by resistive evaporation, and the low-refractive-index material layer is prepared by EBE or resistive evaporation. The high-refractive-index material layer is opposite to the low-refractive-index material layer, and a refractive index of the high-refractive-index material layer is greater than that of the low-refractive-index material layer. There are no special restrictions on the processes and related process parameters for preparing the high-refractive-index material layer and the low-refractive-index material layer, and any process parameters well-known to those skilled in the art may be employed in the present disclosure. In an embodiment of the present disclosure, the polarizing beam splitting coating 2 is prepared as follows. Deposition is performed by resistive evaporation. Specifically, the diamond substrate with the metallized layer prepared is mounted. A door of a vacuum chamber is closed, and vacuum pumping is performed until a base pressure reaches 1.0×10⁻³ Pa. Then a workpiece tray is activated to rotate at a speed of 10 rpm. Substrate baking is initiated, with the temperature set to 160° C. When the baking time reaches 120 min, the speed of the workpiece tray is adjusted to 20 rpm. An ion source is turned on to perform pre-deposition bombardment cleaning on the diamond substrate for 5 min. Then the ion source is turned off. The ZnSe and BaF₂ doped with YbF₃ are deposited. The two materials are deposited using a multi-position rotary resistive evaporation source, with deposition rates of 4.0 nm/s and 5.0 nm/s, respectively. The preparation of the polarizing beam splitting coating 2 is completed according to the film stack shown in Table 1. After the preparation, the sample is naturally cooled to below 80° C. and then taken out of the vacuum chamber.

In the present disclosure, the broadband anti-reflection coating 3 is prepared on the remaining area of the one side surface of the diamond substrate 1. Preferably, the high-refractive-index material layer is prepared by resistive evaporation, and the low-refractive-index material layer is prepared by EBE or resistive evaporation. There are no special restrictions on the processes and related process parameters for preparing the high-refractive-index material layer and the low-refractive-index material layer, and any process parameters well-known to those skilled in the art may be employed in the present disclosure. In an embodiment of the present disclosure, the broadband anti-reflection coating 3 may be prepared as follows. Deposition is performed by resistive evaporation. Specifically, the diamond substrate with the metallized layer and the polarizing beam splitting coating prepared is mounted. The door of the vacuum chamber is closed, and vacuum pumping is performed until the base pressure reaches 1.0×10⁻³ Pa. Then the workpiece tray is activated to rotate at a speed of 10 rpm. The substrate baking is initiated, with the temperature set to 160° C. When the baking time reaches 120 min, the speed of the workpiece tray is adjusted to 20 rpm. Then the ion source is turned on to perform pre-deposition bombardment cleaning on the diamond substrate for 5 min. The ion source is turned off, and ZnSe and BaF₂ doped with YbF₃ are deposited. The two materials are deposited by a multi-position rotary resistive evaporation source, at deposition rates of 4.0 nm/s and 5.0 nm/s, respectively. The preparation of the broadband anti-reflection coating 3 is completed according to the film stack shown in Table 2. After the preparation, the sample is naturally cooled to below 80° C. and then taken out of the vacuum chamber.

The present disclosure further provides a use of the polarizing beam splitter according to the above technical solution, or the polarizing beam splitter prepared by the preparation method according to the above technical solution, in a field of an infrared laser annealing device for a semiconductor chip industry and a laser produced plasma (LPP)-driven laser light source for an extreme ultraviolet (EUV) lithography system. There are no special restrictions on the method of the use, and any method well-known to those skilled in the art may be employed in the present disclosure.

The polarizing beam splitter, the preparation method thereof, and the use thereof provided by the present disclosure are described in detail below with reference to embodiments, but they should not be construed as limiting the protection scope of the present disclosure.

### Embodiment 1

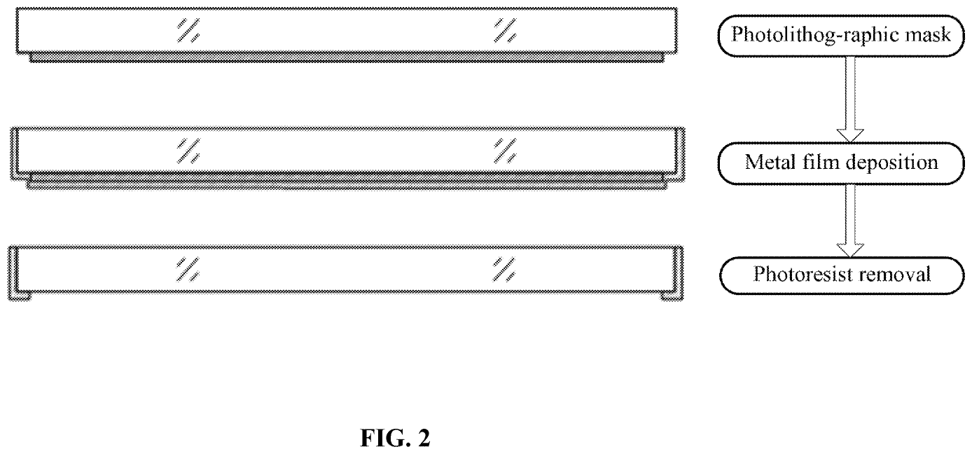

A double-side polished CVD diamond with a diameter Φ of 50 mm and a thickness of 2 mm is used as the diamond substrate. The metallized layer (with a thickness of 1.5 μm, and a width of 2 mm on the edge of another side surface of the diamond substrate) is prepared by a lift-off process. The specific preparation process (as shown in FIG. 2, using Au with a purity of 99.99% to prepare the metallized layer) is as follows. A 5 μm photoresist is uniformly applied to the one side surface of the diamond substrate. Exposure and development are performed to expose a deposition area of the metallized layer. A photoresist-coated area after exposure and development has a size of

$$Φ {46}_{+ 0.05}^{+ 0.1}$$

mm, which ensures that the polarizing beam splitter has a sufficient aperture. The metallized layer is prepared by resistive evaporation. After exposure and development, the diamond substrate is mounted. The door of the vacuum chamber is closed, and vacuum pumping is performed until the base pressure reaches 8.0×10⁻⁴ Pa. Then the workpiece tray is activated to rotate at a speed of 20 r/min. The ion source is turned on to perform pre-deposition bombardment cleaning on the diamond substrate for 5 min. Then the ion source is turned off, and the deposition of the metallized layer is started. A Ni—Cr alloy layer forms the adhesion layer, which improves the adhesion between the Au layer and the diamond substrate. A spiral tungsten filament is used as a resistive evaporation source for depositing the Ni—Cr alloy layer, with a deposition rate of 6.0 nm/s and a deposition thickness of 50 nm. A molybdenum boat is used as an evaporation source for depositing the Au layer, with a deposition rate of 5.0 nm/s and a deposition thickness of 1.5 μm. After 30 min of preparation, the prepared sample is taken out of the vacuum chamber. The photoresist is stripped to obtain the second metallized layer 4-2 and the first metallized layer 4-1 with a thickness of 1.5 μm.

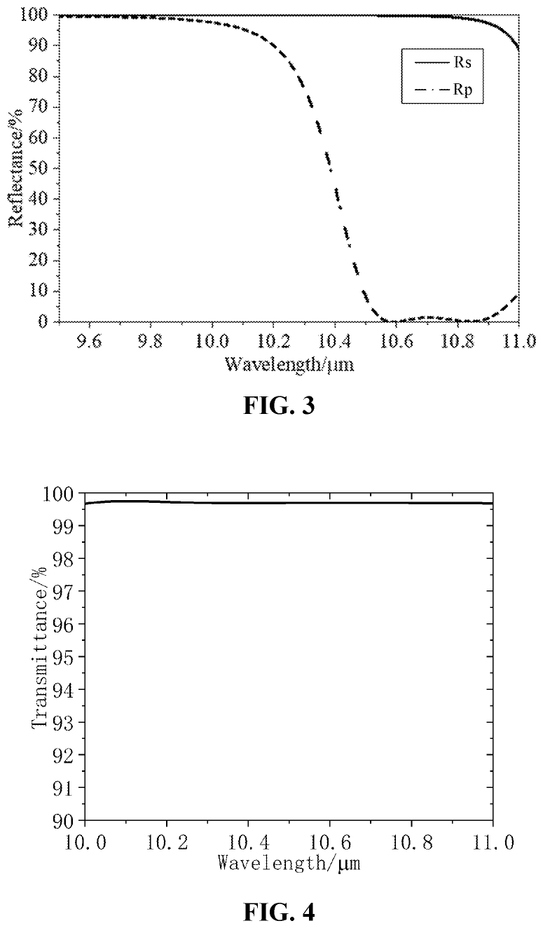

The polarizing beam splitting coating is deposited by resistive evaporation. Specifically, the diamond substrate with the metallized layer prepared is mounted. The door of the vacuum chamber is closed, and vacuum pumping is performed until the base pressure reaches 1.0×10⁻³ Pa. Then the workpiece tray is activated to rotate at a speed of 10 rpm. The substrate baking is initiated, with the temperature set to 160° C. When the baking time reaches 120 min, the speed of the workpiece tray is adjusted to 20 rpm. The ion source is turned on to perform pre-deposition bombardment cleaning on the diamond substrate for 5 min. Then the ion source is turned off, and the deposition of ZnSe and BaF₂ doped with YbF₃ is started. The two materials are deposited by a multi-position rotary resistive evaporation source, with the deposition rate of ZnSe being 4.0 nm/s, and the deposition rate of BaF₂ doped with YbF₃ being 5.0 nm/s. The preparation of the polarizing beam splitting coating 2 is completed according to the film stack shown in Table 1. After the preparation, the sample is naturally cooled to below 80° C. and then taken out of the vacuum chamber. In the polarizing beam splitting coating, the first high-refractive-index material layer is made of ZnSe, the first low-refractive-index material layer is made of BaF₂ doped with YbF₃. The doping amount of YbF₃ in BaF₂ doped with YbF₃ is 1.5 wt %. The thickness of the polarizing beam splitting coating is 36 μm, and the polarizing beam splitting coating includes a total of 31 layers. FIG. 3 is a designed spectrum of the polarizing beam splitting coating 2. It can be seen from FIG. 3 that the Rs value of the polarizing beam splitting coating is greater than 99%, and the Rp value thereof is less than 0.1%.

TABLE 1
Materials and thicknesses of each layer
of the polarizing beam splitting coating

| No. | Material | Coating thickness (nm) |
|---|---|---|
| 1 | ZnSe | 322.23 |
| 2 | BaF₂ | 980.53 |
| 3 | ZnSe | 1727.73 |
| 4 | BaF₂ | 978.42 |
| 5 | ZnSe | 1777.3 |
| 6 | BaF₂ | 923.08 |
| 7 | ZnSe | 1563.3 |
| 8 | BaF₂ | 966.59 |
| 9 | ZnSe | 1654.11 |
| 10 | BaF₂ | 986.45 |
| 11 | ZnSe | 1693.51 |
| 12 | BaF₂ | 974.62 |
| 13 | ZnSe | 2015.6 |
| 14 | BaF₂ | 976.31 |
| 15 | ZnSe | 1874 |
| 16 | BaF₂ | 976.31 |
| 17 | ZnSe | 1885.53 |
| 18 | BaF₂ | 984.33 |
| 19 | ZnSe | 1733.62 |
| 20 | BaF₂ | 940.82 |
| 21 | ZnSe | 1321.57 |
| 22 | BaF₂ | 820.42 |
| 23 | ZnSe | 117.31 |
| 24 | BaF₂ | 883.79 |
| 25 | ZnSe | 1255.79 |
| 26 | BaF₂ | 869.85 |
| 27 | ZnSe | 1914.25 |
| 28 | BaF₂ | 836.47 |
| 29 | ZnSe | 1412.37 |
| 30 | BaF₂ | 682.7 |
| 31 | ZnSe | 49.08 |

The broadband anti-reflection coating is deposited by resistive evaporation. Specifically, the diamond substrate with the metallized layer and the polarizing beam splitting coating prepared is mounted. The door of the vacuum chamber is closed, and vacuum pumping is performed until the base pressure reaches 1.0×10⁻³ Pa. The workpiece tray is activated to rotate at a speed of 10 rpm. The substrate baking is initiated, with the temperature set to 160° C. When the baking time reaches 120 min, the speed of the workpiece tray is adjusted to 20 rpm. The ion source is turned on to perform pre-deposition bombardment cleaning on the diamond substrate for 5 min. Then the ion source is turned off, and the deposition of ZnSe and BaF₂ doped with YbF₃ is started. The two materials are deposited using a multi-position rotary resistive evaporation source, with deposition rates of 4.0 nm/s and 5.0 nm/s, respectively. The preparation of the broadband anti-reflection coating 3 is completed according to the film stack shown in Table 2. After the preparation, the sample is naturally cooled to below 80° C. and then taken out of the vacuum chamber to complete the preparation of the entire polarizing beam splitter. In the broadband anti-reflection coating 3, the second high-refractive-index material layer is made of ZnSe, and the second low-refractive-index material layer is made of BaF₂ doped with YbF₃. The doping amount of YbF₃ in BaF₂ doped with YbF₃ is 1.5 wt %. The thickness of the broadband anti-reflection coating 3 is 30.5 μm, and there are 39 layers in total. The thickness of a single layer of the broadband anti-reflection coating 3 is not greater than 2 μm. FIG. 4 is a designed spectrum of the broadband anti-reflection coating 3. It can be seen from FIG. 4 that the transmittance of the broadband anti-reflection coating 3 is greater than 99.5%.

TABLE 2
Materials and thicknesses of each layer
of the broadband anti-reflection coating

| No. | Material | Coating thickness (nm) |
|---|---|---|
| 1 | ZnSe | 291.74 |
| 2 | BaF₂ | 665.89 |
| 3 | ZnSe | 693.48 |
| 4 | BaF₂ | 1465.36 |
| 5 | ZnSe | 575.11 |
| 6 | BaF₂ | 801.43 |
| 7 | ZnSe | 266.63 |
| 8 | BaF₂ | 1522.32 |
| 9 | ZnSe | 571.52 |
| 10 | BaF₂ | 1215.89 |
| 11 | ZnSe | 817.83 |
| 12 | BaF₂ | 1673.57 |
| 13 | ZnSe | 270.22 |
| 14 | BaF₂ | 1155 |
| 15 | ZnSe | 395.76 |
| 16 | BaF₂ | 1555.71 |
| 17 | ZnSe | 424.46 |
| 18 | BaF₂ | 1418.21 |
| 19 | ZnSe | 523.7 |
| 20 | BaF₂ | 438.04 |
| 21 | ZnSe | 589.46 |
| 22 | BaF₂ | 1086.25 |
| 23 | ZnSe | 607.39 |
| 24 | BaF₂ | 699.29 |
| 25 | ZnSe | 847.72 |
| 26 | BaF₂ | 310.36 |
| 27 | ZnSe | 248.7 |
| 28 | BaF₂ | 1917.14 |
| 29 | ZnSe | 126.74 |
| 30 | BaF₂ | 1025.36 |
| 31 | ZnSe | 217.61 |
| 32 | BaF₂ | 355.54 |
| 33 | ZnSe | 298.91 |
| 34 | BaF₂ | 206.25 |
| 35 | ZnSe | 860.87 |
| 36 | BaF₂ | 1648.04 |
| 37 | ZnSe | 612.17 |
| 38 | BaF₂ | 1787.5 |
| 39 | ZnSe | 339.57 |

The above are merely preferred implementations of the present disclosure. It should be noted that a person of ordinary skill in the art may further make several improvements and modifications without departing from the principle of the present disclosure, but such improvements and modifications should be deemed as falling within the protection scope of the present disclosure.

1. A polarizing beam splitter, comprising: a diamond substrate (1), a broadband anti-reflection coating (3) and a first metallized layer (4-1) located on one side surface of the diamond substrate (1), a polarizing beam splitting coating (2) located on another side surface of the diamond substrate (1), and a second metallized layer (4-2) located on a side of the diamond substrate (1), wherein
the first metallized layer (4-1) is located on an edge of the one side surface of the diamond substrate (1), and the broadband anti-reflection coating (3) and the first metallized layer (4-1) are located on the same side surface of the diamond substrate (1);
the polarizing beam splitting coating (2) comprises a first high-refractive-index material layer and a first low-refractive-index material layer that are sequentially stacked and cyclically arranged, and an innermost layer and an outermost layer of the polarizing beam splitting coating (2) are the first high-refractive-index material layer;
the first high-refractive-index material layer is made of zinc selenide (ZnSe);
the first low-refractive-index material layer is made of barium fluoride (BaF₂) doped with ytterbium trifluoride (YbF₃);
the broadband anti-reflection coating (3) comprises a second high-refractive-index material layer and a second low-refractive-index material layer that are sequentially stacked and cyclically arranged, and an innermost layer and an outermost layer of the broadband anti-reflection coating (3) are the second high-refractive-index material layer;
the second high-refractive-index material layer is made of ZnSe;
the second low-refractive-index material layer is made of BaF₂ doped with YbF₃; and
the broadband anti-reflection coating (3) has a thickness ranging from 10 to 50 μm and comprises a total of 39 layers.

2. The polarizing beam splitter according to claim 1, wherein the diamond substrate (1) is double-side polished, has an optical surface shape with a root mean square (RMS) value of less than 1/50 λ, and has a surface roughness of less than 0.5 nm; and
the side of the diamond substrate (1) has a surface roughness of less than 1.6 μm.

3. The polarizing beam splitter according to claim 1, wherein an adhesion layer is provided between the diamond substrate (1) and the first metallized layer (4-1) and between the diamond substrate (1) and the second metallized layer (4-2); and
the adhesion layer is a nickel (Ni)-chromium (Cr) alloy layer.

4. The polarizing beam splitter according to claim 1, wherein the first metallized layer (4-1) and the second metallized layer (4-2) are each independently made of one or more selected from a group consisting of gold (Au), copper (Cu), Cr, and Ni; and
the first metallized layer (4-1) and the second metallized layer (4-2) each independently have a thickness ranging from 1.2 to 2.0 μm.

5. The polarizing beam splitter according to claim 1, wherein the polarizing beam splitting coating (2) has a thickness ranging from 10 to 50 μm and comprises a total of 31 layers.

6. A preparation method of the polarizing beam splitter according to claim 1, comprising following steps:
preparing the second metallized layer (4-2) and the first metallized layer (4-1) on the side of the diamond substrate (1) and on the edge of the one side surface of the diamond substrate; then preparing the broadband anti-reflection coating (3) on a remaining area of the one side surface of the diamond substrate (1), and preparing the polarizing beam splitting coating (2) on the another side surface of the diamond substrate (1), thereby obtaining the polarizing beam splitter.

7. A preparation method of the polarizing beam splitter according to claim 2, comprising following steps:
preparing the second metallized layer (4-2) and the first metallized layer (4-1) on the side of the diamond substrate (1) and on the edge of the one side surface of the diamond substrate; then preparing the broadband anti-reflection coating (3) on a remaining area of the one side surface of the diamond substrate (1), and preparing the polarizing beam splitting coating (2) on the another side surface of the diamond substrate (1), thereby obtaining the polarizing beam splitter.

8. A preparation method of the polarizing beam splitter according to claim 3, comprising following steps:
preparing the second metallized layer (4-2) and the first metallized layer (4-1) on the side of the diamond substrate (1) and on the edge of the one side surface of the diamond substrate; then preparing the broadband anti-reflection coating (3) on a remaining area of the one side surface of the diamond substrate (1), and preparing the polarizing beam splitting coating (2) on the another side surface of the diamond substrate (1), thereby obtaining the polarizing beam splitter.

9. A preparation method of the polarizing beam splitter according to claim 4, comprising following steps:
preparing the second metallized layer (4-2) and the first metallized layer (4-1) on the side of the diamond substrate (1) and on the edge of the one side surface of the diamond substrate; then preparing the broadband anti-reflection coating (3) on a remaining area of the one side surface of the diamond substrate (1), and preparing the polarizing beam splitting coating (2) on the another side surface of the diamond substrate (1), thereby obtaining the polarizing beam splitter.

10. A preparation method of the polarizing beam splitter according to claim 5, comprising following steps:
preparing the second metallized layer (4-2) and the first metallized layer (4-1) on the side of the diamond substrate (1) and on the edge of the one side surface of the diamond substrate; then preparing the broadband anti-reflection coating (3) on a remaining area of the one side surface of the diamond substrate (1), and preparing the polarizing beam splitting coating (2) on the another side surface of the diamond substrate (1), thereby obtaining the polarizing beam splitter.

11. A use of the polarizing beam splitter according to claim 1 in a field of an infrared laser annealing device for a semiconductor chip industry or a laser produced plasma (LPP)-driven laser light source for an extreme ultraviolet (EUV) lithography system.

12. A use of the polarizing beam splitter according to claim 2 in a field of an infrared laser annealing device for a semiconductor chip industry or a laser produced plasma (LPP)-driven laser light source for an extreme ultraviolet (EUV) lithography system.

13. A use of the polarizing beam splitter according to claim 3 in a field of an infrared laser annealing device for a semiconductor chip industry or a laser produced plasma (LPP)-driven laser light source for an extreme ultraviolet (EUV) lithography system.

14. A use of the polarizing beam splitter according to claim 4 in a field of an infrared laser annealing device for a semiconductor chip industry or a laser produced plasma (LPP)-driven laser light source for an extreme ultraviolet (EUV) lithography system.

15. A use of the polarizing beam splitter according to claim 5 in a field of an infrared laser annealing device for a semiconductor chip industry or a laser produced plasma (LPP)-driven laser light source for an extreme ultraviolet (EUV) lithography system.

16. A use of a polarizing beam splitter prepared by the preparation method according to claim 6 in a field of an infrared laser annealing device for a semiconductor chip industry or a laser produced plasma (LPP)-driven laser light source for an extreme ultraviolet (EUV) lithography system.

17. A use of a polarizing beam splitter prepared by the preparation method according to claim 7 in a field of an infrared laser annealing device for a semiconductor chip industry or a laser produced plasma (LPP)-driven laser light source for an extreme ultraviolet (EUV) lithography system.

18. A use of a polarizing beam splitter prepared by the preparation method according to claim 8 in a field of an infrared laser annealing device for a semiconductor chip industry or a laser produced plasma (LPP)-driven laser light source for an extreme ultraviolet (EUV) lithography system.

19. A use of a polarizing beam splitter prepared by the preparation method according to claim 9 in a field of an infrared laser annealing device for a semiconductor chip industry or a laser produced plasma (LPP)-driven laser light source for an extreme ultraviolet (EUV) lithography system.

20. A use of a polarizing beam splitter prepared by the preparation method according to claim 10 in a field of an infrared laser annealing device for a semiconductor chip industry or a laser produced plasma (LPP)-driven laser light source for an extreme ultraviolet (EUV) lithography system.
